(19) United States
(12) Patent Application Publication
(10) Pub. No.: US 2007/0252638 A1
(43) Pub. Date: Nov. 1, 2007

(54) Method and apparatus for temperature compensating off chip driver (OCD) circuit

(76) Inventors: Farrukh Aquil, S. Burlington, VT (US); Josef Schnell, Charlotte, VT (US)

Correspondence Address: EDELL, SHAPIRO & FINNAN, LLC, 1901 RESEARCH BLVD., SUITE 400, ROCKVILLE, MD, 20850, US

(21) Appl. No.: 11/411,145

(22) Filed: Apr. 26, 2006

(51) Int. Cl. H01L 35/00

(52) U.S. Cl. 327/513

(57) ABSTRACT

A method of temperature compensating an off chip driver (OCD) circuit having a plurality of transistor fingers comprising rendering active a normally inactive transistor finger in the circuit when a predetermined temperature condition occurs. A temperature compensated off chip driver (OCD) circuit utilizing such method.

### TECHNICAL FIELD

The invention is directed generally to off chip driver (OCD) circuits, and more particularly to a method and apparatus for compensating such circuits for changes in operating temperature.

### BACKGROUND

When it is necessary to transmit signals off-chip, a circuit known as an off chip driver (OCD) may be used. To be effective, the OCD must deliver signals of sufficient strength and having timing which is within certain margins of error. Figures of merit which are used to define such margins of error include output skew matching ratio, skew between rise and fall delay, and tDQSQ, which will be discussed in further detail below.

An OCD may be implemented in CMOS design and have a group of PMOS field effect transistor (FET) fingers and a group of NMOS FET fingers connected together in push-pull circuit relationship. A problem encountered with such circuits is that the PMOS and NMOS transistors perform differently over different temperature ranges. Thus, at low temperatures (e.g., <5° C.) the PMOS device gets slower and the NMOS device gets faster, while at high temperatures (e.g., >50° C.) the NMOS device signal strength becomes weaker. Due to the different PMOS and NMOS characteristics over the operating temperature range of the circuit, it is difficult to get good performance for tDQSQ and there is a mismatch of the rise and fall times and of the output slew matching ratio.

In a prior design, fuse options are provided to adjust the timing parameters over different temperature, process, and voltage variations. However, such fuse options may not provide adequate control for temperature variations, with the result that the circuit may operate out of specification at certain temperatures.

### SUMMARY OF THE INVENTION

In accordance with the present invention, a method of temperature compensating an off chip driver (OCD) circuit having a plurality of transistor fingers is provided which renders active a normally inactive transistor finger in the OCD circuit when a predetermined temperature condition occurs.

### BRIEF DESCRIPTION OF THE DRAWINGS

The invention will be better understood by referring to the accompanying drawings wherein:

FIG. 1 is a block circuit diagram of a stage of an OCD in accordance with an embodiment of the invention.

FIG. 2 is a block diagram of a multi-stage OCD which may incorporate the invention.

### DETAILED DESCRIPTION

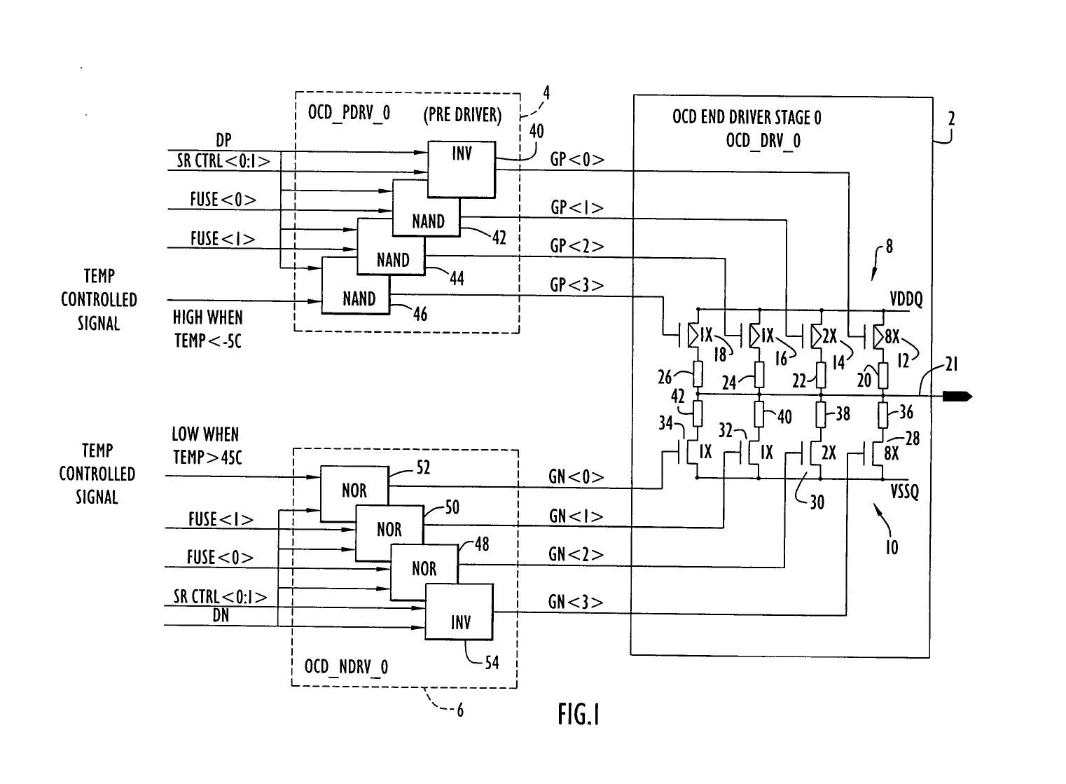

FIG. 1 depicts an embodiment of a stage of the OCD of the invention. As will be seen by referring to FIG. 1, there is an end driver 2 which is fed by pre-drivers 4 and 6.

The end driver in the particular embodiment shown is comprised of a group 8 of PMOS field effect transistor (FET) fingers connected in push-pull circuit relationship with a group 10 of NMOS FET fingers. Both groups of FET fingers include at least one relatively high power FET finger (for example a finger of 8× is depicted) and a plurality of relatively lower power FET fingers (e.g., fingers of 2× and 1× are depicted). The specific PMOS FET group 8 in FIG. 1 is comprised of an 8× finger 12, a 2× finger 14, and 1× fingers 16 and 18. Additionally, resistors 20, 22, 24 and 26 are connected between the respective FET drains and common line 21. Similarly, the NMOS FET group 10 is comprised of 8× finger 28, 2× finger 30, and 1× fingers 32 and 34, while resistors 36, 38, 40 and 42 are connected between the drains of the respective FETs and common line 21. It should be appreciated that the invention is not limited to the number of FET fingers or the power distribution shown, as such may vary in dependence on the particular OCD.

In the embodiment depicted, the source electrodes of the PMOS FET fingers are connected to voltage VDDQ while the source electrodes of the NMOS FET fingers are connected to VSSQ, which in the embodiment shown is at ground potential. When a low signal is applied on a conductor GP to the gate of a PMOS FET, the transistor is turned on. At the same time a low signal is applied on a conductor GN to the gate of a corresponding NMOS FET finger, causing the transistor to turn off. Thus, there is an output signal of voltage magnitude approximately VDDQ appearing between the common line 21 and ground.

On the other hand, when a high signal is applied on a line GN to the gate of an NMOS FET finger, the transistor is turned on, and when a high signal is applied to the gate of a corresponding PMOS FET finger, the transistor is turned off. Thus, there is an output signal of about ground potential on common line 21.

As mentioned above, when the end driver stage is used at operating speed, timing problems can result, and pre-driver stages 4 and 6 are utilized to remedy this. It should be understood that the invention is directed to improving the timing of the driver generally. While there are certain specific figures of merit relating to timing which will be discussed, these are exemplary only, as there are many ways to evaluate how good or bad driver timing may be. A first figure of merit which may be used is the output slew matching ratio which compares the slew of the leading edge of the output signal with the slew of the trailing edge, a matching ratio of “one” being perfect. A second figure of merit is the skew between the rise delay and the fall delay, which is a measurement of the delay between the rising edge of the system clock and the rising and falling edges of the data signal (TAC). Still a third figure of timing merit is tDQSQ which is a measure of the delay between the rising and falling edges of the data strobe signal DQS and the rising and falling edges of the data signal DQ.

Referring again to FIG. 1, as previously noted, the end driver stage is comprised of a plurality of transistor fingers of different powers. The pre-drivers are configured so that the relatively higher power finger (8× in the embodiment depicted) is always active in the circuit by default. On the other hand, one or more of the relatively lower power fingers may be inactive in the circuit and will be selectively rendered active by programming and/or automatic operation of the pre-drivers. Thus, when inactive fingers are activated, the power and speed of the end driver is increased, and so a degree of control over the timing and signal strength is provided.

Referring to FIG. 1, it is seen that pre-driver 4 is comprised of inverter 40 and NAND gates 42, 44, and 46. The data signal DP is inputted to inverter 40 and to one input of each of NAND gates 42, 44, and 46. Thus, when DP goes high, a low signal is inputted on line GP<0> to the gate of PMOS FET finger 12, thus turning the transistor on. An SR CTRL <0:1> line is also inputted to inverter 40. The function of this line is to control the speed of FET finger 12 based primarily on process variations which occur during fabrication of PMOS and NMOS devices and secondarily due to operating voltage and temperature variations (referred to collectively as PVT).

Additionally, NAND gates 42 and 44 have fuses <0> and <1> respectively inputted thereto. When these fuses are set high, during the occurrence of high DP data signals, low signals are outputted from NAND gates 42 and 44, thus turning FET fingers 14 and 16 on. The fuses are selectively set to adjust the timing parameters over different temperature, process and voltage variations. Thus a drive strength trimming range is provided. When the fuses are set high FET fingers 14 and 16 are rendered active in the circuit and when the fuses are set low fingers 14 and 16 are inactive.

However, it was found that when the fuse options were used alone, i.e., without the improvement of the present invention, the device may operate out of specification over certain portions of the temperature range. For example, this could be the case when the OCD is incorporated in a particular low power (LP) dynamic random access memory (DRAM), for which a temperature range of −30° C. to +85° C. is specified.

In accordance with the present invention, a normally inactive FET finger is rendered active in response to a predetermined temperature condition. This provides additional control of timing parameters responsive to operating temperature, as well as additional control of drive strength. As discussed above, when the temperature falls to below about −5° C. the PMOS devices get slower while the NMOS devices get faster. Thus, in the embodiment of FIG. 1 a temperature control input to NAND gate 46 is arranged to go high when the temperature falls to below −5° C. This causes a low signal to occur on line GP<3> when DP goes high. Thus, normally inactive FET finger 18 is rendered active and the transistor turns on when DP goes high. This causes faster operation of the PMOS devices to compensate for their slowing down as a result of lower temperature. The term “rendered active” as used herein means that the finger is rendered functional in the circuit, while the term “inactive” means that it is not functional.

It is noted that pre-driver 6 is comprised of inverter 54, and NOR gates 48, 50, and 52. Data signal DN inputted to inverter 54 is the same as data signal DP discussed above, and the inverter also has an SR CTRL <0:1> input as discussed above. The DN signal is applied to one input of NOR gates 48, 50, and 52, while fuse options are applied to the other inputs of NOR gates 48 and 50. To provide the proper outputs on lines GN<1> and GN<2> the fuses would be set low if it is desired to render active FET fingers 38 and 40.

As discussed above, the NMOS device signal strength gets weaker above about 50° C., so the temperature control input to NOR gate 52 is arranged to go low when the operating temperature exceeds about 45° C., thus causing normally inactive FET finger 34 to be rendered active. This provides additional power to the NMOS devices to compensate for the power loss caused by rising temperature. In addition to improving the timing characteristics of the OCD, the present invention also improves the PU/PD current ratio, which relates to the current/voltage characteristics of the PMOS and NMOS devices.

It is noted that the term “temperature” as used herein refers to the operating temperature at the chip. Many chips have on-chip temperature sensors, thus making implementation of the invention easier.

It is also noted that while the illustrative embodiment depicts CMOS technology (PMOS and NMOS devices) the invention may be implemented in any type of circuitry which is comprised of transistor fingers. Further, the actual temperatures mentioned herein are illustrative only and other specific temperatures may be used.

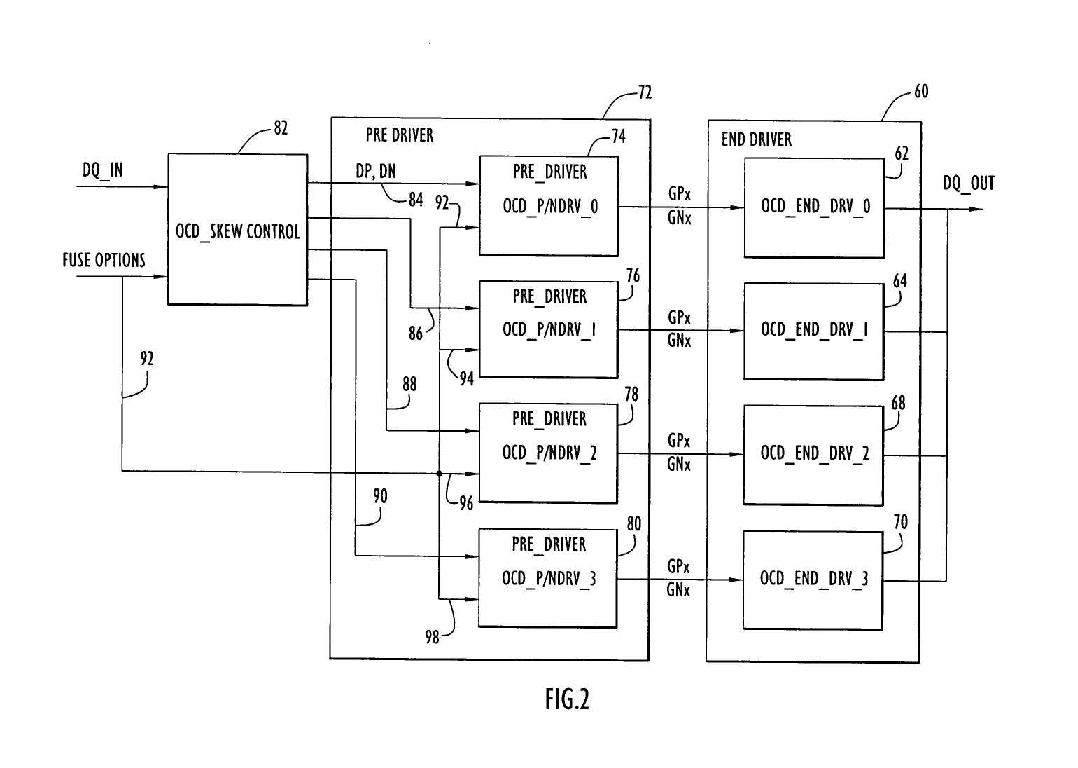

FIG. 2 depicts a multi-stage OCD system comprised of end driver block 60 and pre-driver block 72. End driver block 60 includes end driver stages 62, 64, 68, and 70, while pre-driver block 72 includes pre-driver stages 74, 76, 78, and 80. Each of the end driver stages is similar to end driver stage 2 shown in FIG. 1 and each pre-driver stage incorporates stages similar to pre-driver stages 4 and 6 shown in FIG. 1. OCD skew control 82 has input signal DQ_IN inputted thereto as well as a signal relating to fuse options. The outputs of skew control 82 are the signals DP and DN of FIG. 1, which are fed to pre-drivers 74, 76, 78, and 80 by conductors 84, 86, 88, and 90 respectively. The fuse options signals are also fed to pre-drivers 74, 76, 78, and 80 by conductors 92, 94, 96, and 98 respectively. The skew control 82 introduces a small delay between the turning on of successive stages to control noise in the system. In one embodiment, by way of non-limitative example a 200 picosecond delay is introduced between activation of successive stages. The fuse options signal is also fed to skew control 82 since the fuse options may have an effect on the amount of delay introduced.

The end driver and pre-driver stages operate as described in connection with FIG. 1. If a fuse is set or a temperature control finger is rendered active in one stage, such setting or rendering active may be effected in all stages. The output of the OCD system is DQ.

There thus has been described an improved method and apparatus for compensating OCD circuits for changes in operating temperature. The system and methods described herein may be embodied in other specific forms without departing from the spirit or essential characteristics thereof. The foregoing embodiments are therefore to be considered in all respects illustrative and not meant to be limiting.

What is claimed is:

1. A method of temperature compensating an off chip driver (OCD) circuit having a plurality of transistor fingers, comprising:
rendering active a normally inactive transistor finger in the circuit in response to occurrence of a predetermined temperature condition.

2. The method of claim 1, wherein said plurality of transistor fingers comprises a plurality of PMOS field effect transistor (FET) fingers and wherein said predetermined temperature condition is when said temperature falls below a certain value.

3. The method of claim 2, further comprising:
rendering active a normally inactive second transistor finger in the circuit in response to occurrence of a second predetermined temperature condition.

4. The method of claim 3 wherein said plurality of transistor fingers further comprises a plurality of NMOS FET fingers which includes said second transistor finger, said NMOS FET fingers being connected in circuit relationship with said PMOS FET fingers, and said second predetermined temperature condition being when said temperature rises above a certain value.

5. The method of claim 2 wherein, when said normally inactive transistor is rendered active, the timing of the OCD circuit is improved.

6. A temperature compensated off chip driver (OCD) circuit, comprising:
a group of transistor fingers having a temperature dependent property which may affect the operation of the circuit; and
a logic gate which receives a temperature control signal at an input responsive to the occurrence of a predetermined temperature condition and which has an output connected to a first normally inactive transistor finger in said group of transistor fingers for rendering active said first transistor finger in response to receiving said temperature control signal.

7. The OCD circuit of claim 6, wherein said group of transistor fingers comprises a plurality of PMOS field effect transistor (FET) fingers and wherein said predetermined temperature condition is when said temperature falls below a certain value.

8. The OCD circuit of claim 7, comprising:
a second group of transistor fingers having a temperature dependent property which may affect the operation of the circuit; and
a second logic gate which receives a second temperature control signal at an input responsive to the occurrence of a second predetermined temperature condition and which has an output connected to a second normally inactive transistor finger in said second group of transistor fingers for rendering active said second transistor finger in response to reception of said second predetermined temperature signal.

9. The OCD circuit of claim 8 wherein said second group of transistor fingers comprises a plurality of NMOS field effect transistor (FET) fingers and wherein said predetermined temperature condition is when said temperature rises above a preselected value.

10. The OCD circuit of claim 9 wherein said first logic gate comprises an AND type gate and wherein said second logic gate comprises an OR type gate.

11. A temperature compensated off chip driver (OCD) circuit, comprising:
a first group of PMOS field effect transistor (FET) fingers;
a second group of NMOS field effect transistor (FET) fingers connected in push-pull circuit relationship with said first group of FET fingers;
a first logic gate which receives a first temperature control signal at an input in response to the temperature falling below a first predetermined value and which has an output connected to a first normally inactive transistor finger in said first group of transistor fingers; and
a second logic gate which receives a second temperature control signal at an input in response to the temperature rising above a second predetermined value and which has an output connected to a second normally inactive transistor finger in said second group of transistor fingers.

12. The OCD circuit of claim 11 wherein each group of transistor fingers is comprised of a relatively higher power transistor and a plurality of relatively lower power transistors.

13. The OCD circuit of claim 12 wherein said normally inactive transistor fingers comprise relatively lower power transistors.

14. The OCD of claim 13 wherein a settable fuse is connected in circuit relationship with a relatively lower power transistor.

15. The OCD of claim 14 wherein said first logic gate comprises an AND type gate and wherein said second logic gate comprises an OR type gate.

16. A temperature compensated off chip driver (OCD) circuit, comprising:
transistor finger means comprised of a group of transistor fingers having a temperature dependent property which may affect the operation of the circuit; and
means responsive to a predetermined temperature condition for rendering active a normally inactive transistor finger in said group of said transistor fingers.

17. The OCD circuit of claim 16 wherein said group of transistor fingers comprises a plurality of PMOS field effect transistor (FET) fingers and wherein said predetermined temperature condition is when said temperature falls below a preselected value.

18. The OCD circuit of claim 17 wherein said transistor finger means includes a second group of transistor fingers having a temperature dependent property which may affect the operation of the circuit, further comprising means responsive to a second predetermined temperature condition for rendering active a second normally inactive transistor finger in said second group of transistor fingers.

19. The OCD circuit of claim 18 wherein said second group of transistor fingers comprises a plurality of NMOS field effect transistor (FET) fingers and wherein said predetermined temperature condition is when said temperature rises above a preselected value.

20. The OCD circuit of claim 19 further comprising means for connecting said groups of transistor fingers together so as to operate in a push-pull manner.

21. A temperature compensated off chip driver (OCD) system comprising:
a plurality of end driver stages;
a plurality of pre-driver stages, each of which is associated with an end driver stage;
each end driver stage comprising a group of PMOS field effect transistor (FET) fingers and a group of NMOS FET fingers connected together in circuit relationship; and
each pre-driver stage comprising logic circuitry responsive to the temperature falling below a predetermined value to render active a first normally inactive PMOS FET finger and to the temperature rising above a predetermined value to render active a second normally inactive NMOS FET finger.

22. The OCD system of claim 21 wherein each of said groups of FET fingers includes a finger having a relatively higher power transistor and a plurality of fingers having relatively lower power transistors, and wherein said first and second normally inactive FET fingers comprise relatively lower power transistors.

23. The OCD system of claim 22 wherein each pre-driver stage includes settable fuses to which said logic circuitry is responsive for rendering active further fingers having relatively lower power transistors.

24. The OCD circuit of claim 23 wherein the groups of transistor fingers are arranged to operate in push-pull manner.

25. The OCD circuit of claim 24 further comprising a skew controller arranged to activate said stages of the driver with a time offset from each other.
